(19) United States
(12) Patent Application Publication
(10) Pub. No.: US 2024/0421106 A1
(43) Pub. Date: Dec. 19, 2024

(54) POWER MODULE

(71) Applicants: Hyundai Motor Company, Seoul (KR); Kia Corporation, Seoul (KR)

(72) Inventors: Jin Myeong YANG, Seongnam-Si (KR); Sung Won PARK, Incheon (KR); Han Jin DO, Incheon (KR)

(73) Assignees: Hyundai Motor Company, Seoul (KR); Kia Corporation, Seoul (KR)

(21) Appl. No.: 18/389,512

(22) Filed: Nov. 14, 2023

(30) Foreign Application Priority Data
Jun. 19, 2023 (KR) 10-2023-0078085
Oct. 16, 2023 (KR) 10-2023-0137726

(51) Int. Cl. H01L 23/48; H01L 23/00; H01L 23/498; H01L 23/64

(52) U.S. Cl. CPC H01L 23/647; H01L 23/3735; H01L 23/49833; H01L 23/49844; H01L 24/32; H01L 2224/32227; H01L 2924/13055; H01L 2924/13091

(57) ABSTRACT

Introduced is a power module including a first substrate and a second substrate, a semiconductor chip, and a via spacer electrically connecting the first substrate and the second substrate, wherein the via spacer includes a first portion electrically connected to the first substrate, a second portion electrically connected to the second substrate, and a resistor portion including a resistance value greater than resistance values of the first portion and the second portion and arranged between the first portion and the second portion.

### CROSS REFERENCE TO RELATED APPLICATION

The present application claims priority to Korean Patent Application Nos. 10-2023-0078085, filed Jun. 19, 2023, and 10-2023-0137726, filed Oct. 16, 2023, the entire contents of which is incorporated herein for all purposes by this reference.

### BACKGROUND OF THE PRESENT DISCLOSURE

### Field of the Present Disclosure

The present disclosure relates to a power module equipped with via spacers for internal current conduction and sensing.

### Description of Related Art

With the growing interest in the environment, there is a trend of increasing eco-friendly vehicles equipped with electric motors as power sources. Eco-friendly vehicles, also known as electrified vehicles, include electric vehicles (EVs) and hybrid electric vehicles (HEVs).

In electrified vehicles, an inverter is typically equipped to convert direct current power to alternating current power for motor operation, and the inverter is usually composed of one or multiple power modules incorporating semiconductor chips that perform switching functions.

To control the power conversion system of a vehicle incorporating power modules, it is necessary to detect the current of the power modules, which may be achieved by equipping external current sensors or integrating resistive elements such as shunt resistors internally within the power modules.

If resistive elements such as shunt resistors are integrated inside the power modules, it is necessary to appropriately manage the heat generation of these resistive elements and the formation of current loops within the power module caused by the flow of high currents.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module which is configured for establishing electrical connection between a plurality of substrates through via spacers with a resistive element, while simultaneously allowing for current sensing within the module.

The objects of the present disclosure are not limited to the aforesaid, and other objects not described herein will be clearly understood by those skilled in the art from the descriptions below.

In order In various aspects of the present disclosure, a power module according to an exemplary embodiment of the present disclosure includes a first substrate and a second substrate including each an insulating layer and a metal layer disposed on one surface of the insulating layer and arranged, spaced from each other, for the metal layers to face each other, a semiconductor chip disposed between the first substrate and the second substrate, and a via spacer extending in a first direction, electrically connecting the first substrate and the second substrate, between the first substrate and the second substrate and separated from the semiconductor chip with a predetermined distance in a second direction crossing the first direction, wherein the via spacer includes a first portion electrically connected to the first substrate, a second portion electrically connected to the second substrate, and a resistor portion including a resistance value greater than resistance values of the first portion and the second portion and arranged along the first direction between the first portion and the second portion.

For example, the first portion and the second portion may extend in the same length in the first direction, and the resistor portion may be disposed at the center portion of the via spacer.

For example, the resistor portion may extend in the same length as the first portion and the second portion in the second direction.

For example, the potentials of the first portion and the second portion may be transferred to at least one of the first substrate and the second substrate.

For example, at least one of the first substrate and the second substrate may include a plurality of patterns individually formed to receive the potentials.

For example, the first portion and the second portion may each be connected to the plurality of patterns through a wire.

For example, the plurality of patterns may be connected to a signal lead transferring the received potentials to the outside thereof.

For example, the via spacer may receive first current passed through the semiconductor chip through one of the first substrate and the second substrate and transfer the received first current to the other substrate.

For example, the resistor portion may receive second current separate for sensing the first current, separately from the first current.

For example, the second current may include a current value less than that of the first current.

Through various embodiments of the present disclosure as described above, it becomes possible to implement a current sensor within the power module through via spacers, improving sensing performance by reducing sensing errors compared to the case where the current sensor is located outside the power module.

Furthermore, compared to the case where the current sensor is located outside the power module, the arrangement of additional components for connecting the resistive element may be omitted, resulting in a reduction in the overall volume and cost of the components required for current sensing.

Furthermore, the heat generated during the current sensing may be transferred to the two substrates, allowing for current sensing to be performed at relatively lower temperatures, which leads to the improvement of linearity between temperature and resistance values, enhancing the accuracy of sensing.

Furthermore, it becomes possible to accommodate larger currents with the same size, allowing for further reduction in the volume of components required for current sensing.

Furthermore, by integrating the current sensor and via spacers, which serve separate functions, into a single configuration, it becomes possible to simplify the internal structure of the power module.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram illustrating a configuration of a power module according to an exemplary embodiment of the present disclosure.

FIG. 2 is a diagram illustrating a via spacer of a power module according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below: While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The specific structural or functional descriptions of the exemplary embodiments of the present disclosure included in the present specification or patent application are illustrative examples intended to describe embodiments of the present disclosure, and the exemplary embodiments of the present disclosure may be implemented in various forms and should not be construed as being limited to those described in the present specification or the application.

The exemplary embodiments of the present disclosure may be subject to various modifications and can take on different forms, so specific embodiments are illustrated in the drawings and described in detail in the present specification or the application. However, this should not be construed as limiting the exemplary embodiments of the present disclosure to specific disclosed form, but rather should be understood to encompass all modifications, equivalents, or substitutes that fall within the scope of the concept and technological scope of the present disclosure.

Unless otherwise defined, all terms used herein, including technical or scientific terminology, include the same meaning as commonly understood by those skilled in the art to which the present disclosure belongs. It will be further understood that terms, including those defined in commonly used dictionaries, should be interpreted in a manner consistent with their meaning in the context of the relevant field and should not be interpreted in an idealized or overly formal sense unless explicitly defined in the present specification.

Hereinafter, descriptions include the exemplary embodiments disclosed in the present specification with reference to the accompanying drawings in which the same reference numbers are assigned to refer to the same or like components and redundant description thereof is omitted.

As used in the following description, the suffix “module” and “unit” are granted or used interchangeably in consideration of easiness of description but, by itself, including no distinct meaning or role.

Furthermore, detailed descriptions of well-known technologies related to the exemplary embodiments included in the present specification may be omitted to avoid obscuring the subject matter of the exemplary embodiments included in the present specification. Furthermore, the accompanying drawings are only for easy understanding of the exemplary embodiments included in the present specification and do not limit the technical spirit included herein, and it should be understood that the exemplary embodiments include all changes, equivalents, and substitutes within the spirit and scope of the present disclosure.

As used herein, terms including an ordinal number such as “first” and “second” may be used to describe various components without limiting the components. The terms are used only for distinguishing one component from another component.

It will be understood that when a component is referred to as being “connected to” or “coupled to” another component, it may be directly connected or coupled to the other component or intervening component may be present. In contrast, when a component is referred to as being “directly connected to” or “directly coupled to” another component, there are no intervening component present.

As used herein, the singular forms are intended to include the plural forms as well, unless the context clearly indicates otherwise.

It will be further understood that the terms “comprises” or “has,” when used in the present specification, specify the presence of a stated feature, number, step, operation, component, element, or a combination thereof, but they do not preclude the presence or addition of one or more other features, numbers, steps, operations, components, elements, or combinations thereof.

For example, each controller may include a communication device communicating with another controller or sensor to control a function in charge, a memory that stores operating system or logic instructions and input/output information, and one or more processors for determination, operation, and decision-making necessary for functions in charge.

The power module according to an exemplary embodiment of the present disclosure is provided with via spacers that not only connect a plurality of substrates but also perform the role of current sensing, improving the sensing performance and efficiency of the internal current within the power module and simplifying the internal structure of the power module.

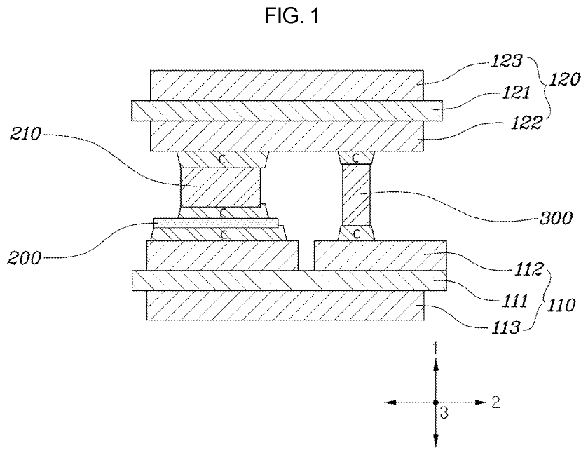

Hereinafter, a description first includes the overall configuration of the power module according to an exemplary embodiment of the present disclosure with reference to FIG. 1.

FIG. 1 is a cross-sectional view exemplarily illustrating the overall configuration of the power module according to an exemplary embodiment of the present disclosure.

With reference to FIG. 1, the power module according to an exemplary embodiment of the present disclosure includes a first substrate 110, a second substrate 120, a semiconductor chip 200, and a via spacer 300. However, it should be noted that FIG. 1 illustrates only the components related to an exemplary embodiment of the present disclosure, and the actual power module may include more or fewer components than shown. Each component will be described in detail hereinafter.

First, the first substrate 110 including an insulating layer 111 and a metal layer 112 disposed on one side of the insulating layer 111 and the second substrate 120 including an insulating layer 121 and a metal layer 122 disposed on one side of the insulating layer 121 are arranged to be spaced from each other so that the metal layers 112 and 122 face each other.

The first substrate 110 and the second substrate 120 may be referred to as the lower substrate or the upper substrate, depending on their vertical arrangement, and in the following description, the first substrate 110 is assumed to be the lower substrate while the second substrate 120 is assumed to be the upper substrate. However, this is for the convenience of explanation, and the arrangement between the first substrate 110 and the second substrate 120 is not limited to the present configuration, and the exemplary embodiments of the present disclosure may be applicable even when the first substrate 110 and the second substrate 120 are arranged in the opposite manner.

The insulating layers 111 and 121 are provided for electrical insulation between the inside and the outside of the power module, and the metal layers 112 and 122 are arranged to face the inside of the power module, allowing for conduction within the power module and forming patterns to establish electrical connections within the power module.

The dual-sided structure of the first substrate 110 and the second substrate 120 allows the heat generated inside the power module to be transferred up and down and cooled, resulting in a dual-sided cooling with high cooling efficiency compared to single-sided cooling. As the cooling efficiency increases, the operating temperature of the power module may decrease, improving operational stability.

Additionally, besides the metal layers 112 and 122, additional metal layers 113 and 123 may be arranged on the opposite sides of the insulating layers 111 and 121, facing the outside of the power module to further improve the cooling efficiency. These additional metal layers 113 and 123 play a role in dissipating the heat generated inside the power module to the external environment through heat exchange with the outside thereof.

Furthermore, to achieve even better cooling efficiency, cooling channels, through which a coolant flows, may be connected to the external side of the additional metal layers 113 and 123. Thermal interface material (TIM) or the like may be applied between the additional metal layers 113 and 123 and the cooling channels to facilitate heat transfer from the substrates 110 and 120 to the cooling channels, or a portion of the substrates 110 and 120 including the additional metal layers 113 and 123 may be inserted into the cooling channels to facilitate heat transfer from the substrates 110 and 120 to the cooling channels.

The insulating layers 111 and 121 may be made of ceramic, while the metal layers 112, 122, 113, and 123 may be made of copper (Cu). In the instant case, the first substrate 110 and the second substrate 120 may be implemented using active metal brazed (AMB) or direct bonded copper (DBC) techniques.

Meanwhile, the semiconductor chip 200 is disposed between the first substrate 110 and the second substrate 120.

The semiconductor chip 200 may be attached to one of the first substrate and the second substrate 110 and 120 through an adhesive C and then connected to the other substrate via a chip spacer 210. FIG. 1 shows the semiconductor chip 200 attached to the first substrate 110, but the placement of the semiconductor chip 200 is not limited to the present arrangement, and semiconductor chip 200 may also be placed on the second substrate 120.

Here, the semiconductor chip 200 may be turned on or off based on a switching signal, and the conductivity between the upper and lower sides of the semiconductor chip 200 may be determined by the ON/OFF state.

The semiconductor chip 200 may be implemented as a switching device such as an insulated gate bipolar transistor (IGBT) or a metal-oxide-semiconductor field-effect transistor (MOSFET).

The via spacer 300 extends in the first direction 1 between the first substrate 110 and the second substrate 120 and is connected to the first substrate 110 and the second substrate 120 by adhesive C, electrically connecting the first substrate and the second substrate 110 and 120, while being positioned away from the semiconductor chip 200 in the second direction 2 crossing the first direction 1 thereof.

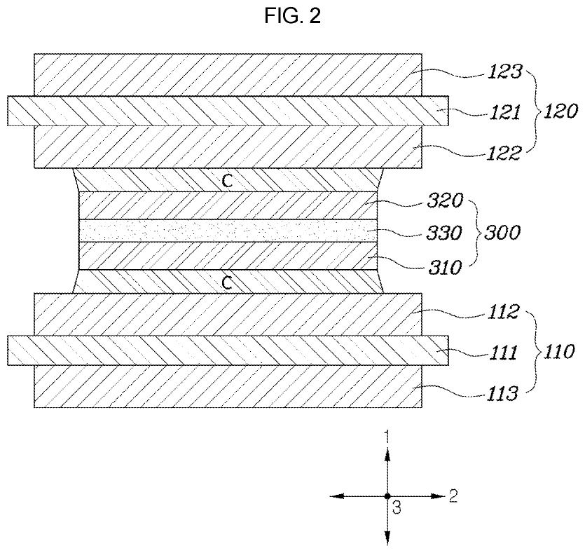

The via spacer 300 is described in more detail with reference to FIG. 2 hereinafter.

FIG. 2 is a diagram illustrating the via spacer of the power module according to an exemplary embodiment of the present disclosure.

With reference to FIG. 2, the via spacer 300 may be divided into a first portion 310, a second portion 320, and a resistor portion 330.

In detail, the first portion 310 is electrically connected to the first substrate 110, while the second portion 320 is electrically connected to the second substrate 120. The resistor portion 330 may have a higher resistance compared to the first portion and the second portion 310 and 320 and is positioned between the first portion and the second portion 310 and 320 in the first direction.

The first portion and the second portion 310 and 320 may extend in the same length in the first direction, and the resistor portion 330 may be positioned at the center portion of the via spacer 300 between the equal lengths of the first portion and the second portion 310 and 320.

Additionally, the resistor portion 330 may extend in the second direction to the same length as the first portion and the second portion 310 and 320, resulting in a consistent cross-sectional shape of the via spacer 300 in the second direction.

By incorporating the resistor portion 330 in the via spacer 300, the current flowing into the via spacer 300 may pass through the resistor, and the current passing through the resistor may be transferred back to the first substrate 110 or the second substrate 120.

The via spacer 300 is configured to electrically connect the first substrate 110 and the second substrate 120 within the power module and is distinguished from the chip spacer 210 in that the via spacer 300 connects the first substrate and the second substrate 110 and 120 in the state of being separated from the semiconductor chip 200 in the second direction rather than connecting the semiconductor chip 200 to the first substrate and the second substrate 110 and 120.

Furthermore, the via spacer 300 may also serve as a sensor configured for sensing the current within the power module. Sensing the current within the power module may be achieved by utilizing the potential difference between the two end portions of the resistor portion 330 connected to the first portion and the second portion 310 and 320, as well as the resistance value of the resistor portion 330.

For example, when the current flown into the first portion 310 of the power module passes through the resistor portion 330 and then exits through the second portion 320, a voltage drop occurs due to the resistance in the resistor portion 330, leading to the generation of a potential difference between the first portion 310 and the second portion 320.

In the instant case, the resistance value of the resistor element 400 may be determined based on the temperature of the power module.

By utilizing the potential difference and resistance value of the resistor portion 330, the current value inside the power module may be known, and the controller connected to the power module may perform control of a motor driven by the power module based on such sensing results.

For the present purpose, the potentials of the first portion and the second portion 310 and 320 may be transmitted to at least one of the first substrate and the second substrate 110 and 120.

For example, the potential of the first portion 310 may be transmitted to the first substrate 110 while the potential of the second portion may be transmitted to the second substrate 120, or both the potentials of the first portion and the second portion 310 and 320 may be transmitted to either the first substrate 110 or the second substrate 120.

However, even when the potentials of the first portion and the second portion 310 and 320 are both transmitted to one of the first substrate and the second substrate 110 and 120, the potentials of the first and second portions 310 and 320 are transmitted in a separated state.

Furthermore, at least one of the first substrate and the second substrate 110 and 120 may include a plurality of patterns individually formed to receive the potentials of the first portion and the second portion 310 and 320. In the instant case, the plurality of patterns may be electrically isolated from other portions of the substrate for current sensing.

These patterns may be connected by wires, and the first portion and the second portion 310 and 320 may be electrically connected to the plurality of patterns through the wires.

Furthermore, signal leads for transmitting the received potentials to the outside may be connected to the plurality of patterns formed in at least one of the first substrate and the second substrate 110 and 120.

By performing current sensing through the via spacer 300 inside the power module, it is possible to eliminate the need to arrange additional components for current sensing compared to the case where a separate current sensor is provided outside the power module.

This allows for advantages in terms of the volume and cost of components required for current sensing. Furthermore, the performance of current sensing may also be improved compared to using an external current sensor.

Meanwhile, as the resistor portion 330 is connected to the first portion and the second portion 310 and 320, the heat generated by the current flowing through the resistor portion 330 may be transferred to both sides of the substrates 110 and 120. This provides an advantage in heat dissipation during the current sensing process compared to the case where the resistor element 400 is connected to only one side of the substrate 110 or 120, allowing heat to be dissipated in a single direction.

Considering that the linearity between temperature and resistance value decreases as the temperature of the resistor portion 330 increases, heat dissipation in both directions facilitates reducing the temperature of the resistor portion 330, improving the linearity between temperature and resistance value and enhancing the accuracy of current sensing.

Meanwhile, the current flowing through the semiconductor chip 200 and transmitted to the via spacer 300 is referred to as the first current in the following description, and the via spacer 300 may receive the first current through one of the first substrate and the second substrate 110 and 120 and transmit the first current to the other substrate. Here, the first current may be understood as the current which is the target of sensing.

For example, the path of the first current may be of ‘first substrate 110—semiconductor chip 200—chip spacer 210—second substrate 120—second portion 320—resistor portion 330—first portion 310—first substrate 110.’

Meanwhile, a second current, which is separate from the first current, may be applied to the resistor portion 330 to detect the first current. That is, the Kelvin contact (or 4-terminal sensing) method may be applied to the current sensing of the power module according to an exemplary embodiment of the present disclosure.

This allows for improved sensing accuracy even with a low resistance value of the resistor element 400 and a high internal current (i.e., the first current) in the power module.

The second current may include a smaller magnitude compared to the first current, and as the ratio of the second current to the first current decreases, the sensing accuracy may be further enhanced.

Meanwhile, in the case where the via spacer 300 according to various exemplary embodiments of the present disclosure is not applied, a spacer is placed between the first substrate 110 and the second substrate 120 for electrical connection, and a shunt resistor for current sensing may be disposed on the first substrate 110 separately from the spacer.

In the instant case, the shunt resistor is connected to the first substrate 110 but not to the second substrate 120 and thus the heat generated from the shunt resistor is transmitted only to the first substrate 110.

Meanwhile, in the power module with the via spacer 300 according to various exemplary embodiments of the present disclosure, the via spacer 300 including the resistor portion 330 doubles as the electrical connection and current sensing between the first substrate 110 and the second substrate 120, simplifying the internal arrangement of the substrate compared to the comparative example.

Furthermore, because the resistor portion 330 is connected to the first substrate and the second substrate 110 and 120 through the first portion and the second portion 310 and 320, the heat generated from the resistor portion 330 may be transferred in both directions, to the first substrate and the second substrate 110 and 120 during the current sensing process, facilitating heat dissipation and allowing current sensing to be performed at relatively low temperatures compared to the comparative example.

Through various embodiments of the present disclosure as described above, it becomes possible to implement a current sensor within the power module through a via spacer, improving sensing performance by reducing sensing errors compared to the case where the current sensor is located outside the power module.

Furthermore, compared to the case where the current sensor is located outside the power module, the arrangement of additional components for connecting the resistive element may be omitted, resulting in a reduction in the overall volume and cost of the components required for current sensing.

Furthermore, the heat generated during the current sensing may be transferred to the two substrates, allowing for current sensing to be performed at relatively lower temperatures, which leads to the improvement of linearity between temperature and resistance values, enhancing the accuracy of sensing.

Furthermore, it becomes possible to accommodate larger currents with the same size, allowing for further reduction in the volume of components required for current sensing.

Furthermore, by integrating the current sensor and via spacers, which serve separate functions, into a single configuration, it becomes possible to simplify the internal structure of the power module.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
a first substrate and a second substrate, each of which includes an insulating layer and a metal layer disposed on one surface of the insulating layer, wherein the metal layers are arranged and spaced from each other to face each other in a first direction;
a semiconductor chip disposed between the first substrate and the second substrate in the first direction; and
a via spacer extending in the first direction, electrically connecting the first substrate and the second substrate, between the first substrate and the second substrate and separated from the semiconductor chip with a predetermined distance in a second direction crossing the first direction,
wherein the via spacer includes:
a first portion electrically connected to the first substrate;
a second portion electrically connected to the second substrate; and
a resistor portion including a resistance value greater than resistance values of the first portion and the second portion and arranged between the first portion and the second portion in the first direction.

2. The power module of claim 1, wherein the first portion and the second portion extend in a same length in the first direction, and the resistor portion is disposed at a center portion of the via spacer.

3. The power module of claim 1, wherein the resistor portion extends in a same length as the first portion and the second portion in the second direction.

4. The power module of claim 1, wherein potentials of the first portion and the second portion are transferred to at least one of the first substrate and the second substrate.

5. The power module of claim 4, wherein at least one of the first substrate and the second substrate includes a plurality of patterns individually formed to receive the potentials.

6. The power module of claim 5, wherein the first portion and the second portion are each connected to the plurality of patterns through a wire.

7. The power module of claim 5, wherein the plurality of patterns are connected to a signal lead transferring the received potentials to an outside of the power module.

8. The power module of claim 1, wherein the via spacer receives a first current passed through the semiconductor chip through one of the first substrate and the second substrate and transfers the received first current to another of the first substrate and the second substrate.

9. The power module of claim 8, wherein the resistor portion receives a second current for sensing the first current, separately from the first current.

10. The power module of claim 9, wherein the second current includes a current value less than a current of the first current.

11. The power module of claim 1, further including a chip spacer connecting a first surface of the semiconductor chip to one of the first substrate and the second substrate and a second surface of the semiconductor chip is connected to a remaining one of the first substrate and the second substrate.

12. The power module of claim 11, wherein the chip spacer is connected to the first surface of the semiconductor chip and the one of the first substrate and the second substrate by an adhesive and the second surface of the semiconductor chip is connected to the remaining one of the first substrate and the second substrate by the adhesive.

13. The power module of claim 1, wherein the first substrate and the second substrate includes additional metal layers arranged on opposite sides of the insulating layers, facing an outside of the power module.
